(19) United States
(12) Patent Application Publication
(10) Pub. No.: US 2026/0333614 A1
(43) Pub. Date: Oct. 22, 2026

(54) SERVER JET-FLOW COOLING DEVICE

(71) Applicant: JWS TECHNOLOGY CO., LTD., New Taipei City (TW)

(72) Inventors: Pang-Hung LIAO, New Taipei City (TW); Chih-Wei CHEN, New Taipei City (TW); Chen-Yuan LO, New Taipei City (TW)

(21) Appl. No.: 19/181,239

(22) Filed: Apr. 16, 2025

(51) Int. Cl. H05K 7/20

(52) U.S. Cl. CPC H05K 7/20145; H05K 7/20154; H05K 7/20172; H05K 7/20254; H05K 7/20509; H05K 7/20727; H05K 7/20772

(57) ABSTRACT

A server jet-flow cooling device having a server and a shunt assembly is provided. The server has a motherboard therein and at least one memory module comprised of a plurality of memories arranged at intervals on the motherboard. An arranged spacing is defined between any two adjacent memories. The shunt assembly is arranged in the server and includes a shunter and at least one first jet-flow tube communicated to the shunter. The first jet-flow tube is extended from a surface of the shunter, extended into one of the arranged spacings, and has a first jet located in one of the arranged spacings to provide a positive pressure or a negative pressure. A jet flow generated by the positive pressure or the negative pressure is therefore cooling the memories in the server.

### BACKGROUND

### Technical Field

The present disclosure relates to a heat dissipation device, particularly to a server jet-flow cooling device.

### Description of Related Art

The existing servers often need to expand the computing power thereof by adding a plurality of memory modules, and each of the memory modules is comprised of a plurality of memories arranged erectly at intervals on a motherboard. Thus, the heat generated by the memories during operation may accumulate between the gaps of the memories and become difficult to dissipate. In particular, a complex electronic member and other dissipating members are arranged in the server, such that it is even more difficult to dissipate the heat by blowing external airflow, such as fans, under various blocking and surrounding configuration.

In view of the above, the inventor seeks to overcome the aforementioned drawbacks associated with the current technology and aims to provide an effective solution through extensive researches along with utilization of academic principles and knowledge.

### SUMMARY

The primary objective of the present disclosure is to provide a server jet-flow device to cool the memories in the server through a jet flow generated by the positive pressure or the negative pressure.

To accomplish the aforementioned objective, the present disclosure provides a server jet-flow cooling device having a server and a shunt assembly. The server has a motherboard therein and at least one memory module arranged on the motherboard. The memory module includes a plurality of memories arranged at intervals on the motherboard. An arranged spacing is defined between any two adjacent memories. The shunt assembly is arranged in the server. The shunt assembly includes a shunter and at least one first jet-flow tube communicated to the shunter. The first jet-flow tube is extended from a surface of the shunter, is extended into one of the arranged spacings, and has a first jet located in one of the arranged spacings to provide a positive pressure or a negative pressure.

### BRIEF DESCRIPTION OF THE DRAWINGS

FIG. 1 is a perspective appearance view of the first embodiment of the present disclosure;

FIG. 2 is a cross-sectional top view of the first embodiment of the present disclosure;

FIG. 3 is a cross-sectional side view of the first embodiment of the present disclosure;

FIG. 3A is a partially enlarged view of another modified design according to FIG. 3;

FIG. 4 is a perspective appearance view of the second embodiment of the present disclosure;

FIG. 5 is a cross-sectional top view of the second embodiment of the present disclosure;

FIG. 6 is a cross-sectional side view of the second embodiment of the present disclosure;

FIG. 6A is a partially enlarged view of another modified design according to FIG. 6; and

FIG. 7 is a perspective appearance view of the third embodiment of the present disclosure.

### DETAILED DESCRIPTION

The technical contents of the present disclosure will become apparent with the detailed description of embodiments and the accompanied drawings as follows. However, it shall be noted that the accompanied drawings are for illustrative purposes only such that they shall not be used to restrict the scope of the present disclosure.

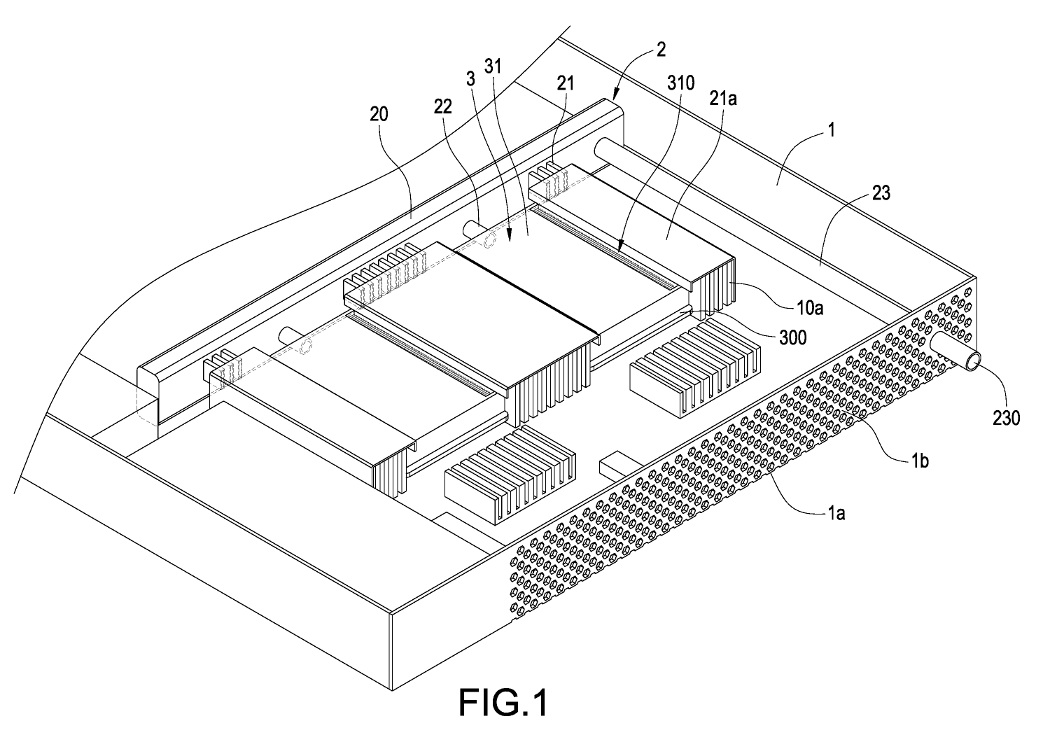

Please refer to FIGS. 1, 2, 3, which are respectively the perspective appearance view, the cross-sectional top view, and the cross-sectional side view of the first embodiment of the present disclosure. The present disclosure provides a server jet-flow cooling device including a server 1 and a shunt assembly 2 arranged in the server 1. The server 1 has a motherboard 1a therein and at least one memory module 10 arranged on the motherboard 1a. The memory module 10 includes a plurality of memories 10a arranged at intervals on the motherboard 1a. Furthermore, the server 1 further includes at least one electronic member 11 arranged on the motherboard 1a. The electronic member 11 may be any electronic computing unit or computing element, such as a central processing unit (CPU).

The shunt assembly 2 includes a shunter 20 and at least one first jet-flow tube 21 communicated to the shunter 20 and extended from the shunter 20. Furthermore, the shunt assembly 2 further includes at least one second jet-flow tube 22. The first jet-flow tube 21 is corresponding to the memory module 10, and the second jet-flow tube 22 is corresponding to the electronic member 11. In detail, the shunter 20 is extended along an arranged direction of each of the memories 10a of the memory modules 10 to form elongated strip shape. The first jet-flow tube 21 and the second jet-flow tube 22 are arranged on a surface of the shunter 20 facing each of the memories 10a and communicated to each other. The shunter 20 may be provided with a positive pressure or a negative pressure through a stressor (not shown in figures), and the stressor is arranged inside or outside the server 1. In the embodiment, the shunt assembly 2 further includes a connecting tube 23 extended from the shunter 20 and toward outside of the server 1, such that the stressor outside may provide the positive pressure or the negative pressure to the shunter 20. As shown in FIG. 1, the connecting tube 23 is extended from an end surface 1b of the server 1 to define a connecting port 230, such that the connecting port 230 may connect the stressor with other connecting members or pipes. In addition, the connecting port 230 may achieve ventilation effect, such as through defining a ventilation hole.

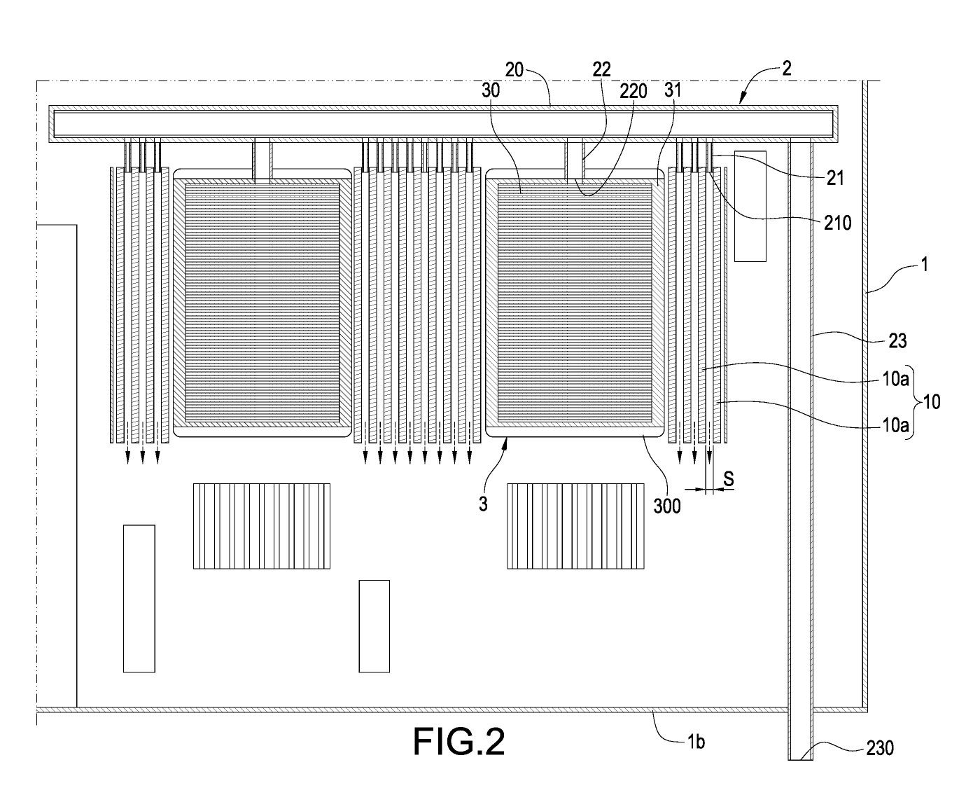

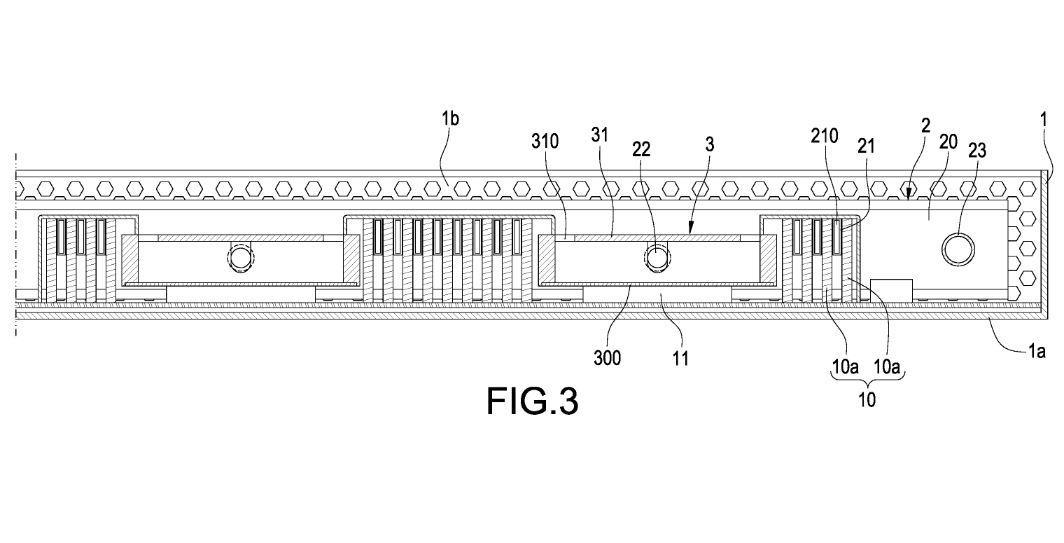

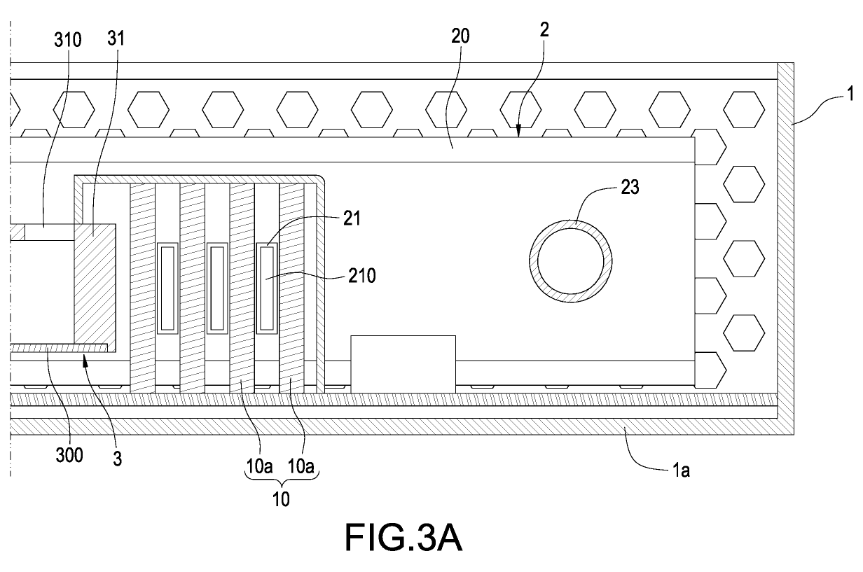

As shown in FIG. 2, an arranged spacing S is defined between any two adjacent memories 10a. The first jet-flow tube 21 is extended from a surface of the shunter 20, is extended into one of the arranged spacings S, and has a first jet 210 located in one of the arranged spacings S to discharge the heat generated by each of the memories 10a during operation when the stressor provides the positive pressure or the negative pressure. For example, when the stressor provides the positive pressure as shown in FIG. 2, the first jet 210 may discharge the heat in the arranged spacings S toward a direction away from the shunter 20. When the stressor provides the negative pressure as shown in FIG. 3, the first jet 210 may absorb the heat into the shunter 20 to achieve heat dissipation effect. In the embodiment, the first jet-flow tubes 21 is located on an upper area of the arranged spacing S, and the shunt assembly 2 further includes a wind shield 21a arranged on the memory module 10. As shown in FIG. 3A, the first jet-flow tubes 21 may also be located on a middle area of the arranged spacing S. In other embodiments, the first jet-flow tubes 21 may also be located on a lower area (not shown in figures) of the arranged spacing S, or a cross-sectional area of the first jet-flow tubes 21 may be increased such that a cross-sectional shape thereof may be corresponding to a cross-sectional shape of the arranged spacing S, so as to promote heat dissipation effect by completely providing a jet flow into the arranged spacing S with the positive pressure or the negative pressure.

Please refer to FIGS. 2 and 3 again, the server jet-flow cooling device of the present disclosure further includes a cooling unit 3 arranged on the electronic member 11. The cooling unit 3 has a plurality of heat sinks 30 attached on a surface of the electronic member 11 and a cover 31 covering the heat sinks 30. The cover 31 defines a ventilation hole 310. In addition, the second jet-flow tube 22 is extended from a surface of the shunter 20 to pass through the cover 31 and has a second jet 220 located in the cover 31. Therefore, when the stressor provides the positive pressure or the negative pressure, the heat generated by the electronic member 11 during operation may be guided by the heat sinks 30 to discharge by a cold plate 300 attached on the electronic member 11. For example, when the stressor provides the positive pressure, the second jet 220 may discharge the heat of the heat sinks 30 through the ventilation hole 310. When the stressor provides the negative pressure, the second jet 220 may absorb the heat into the shunter 20 to achieve heat dissipation effect.

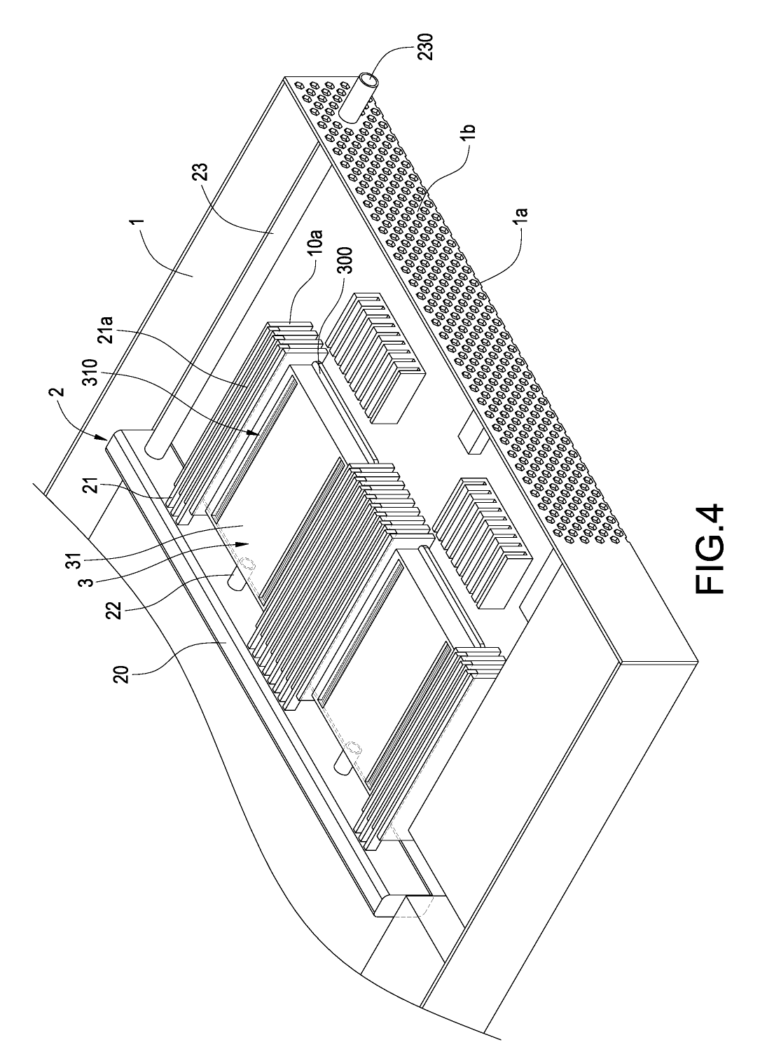

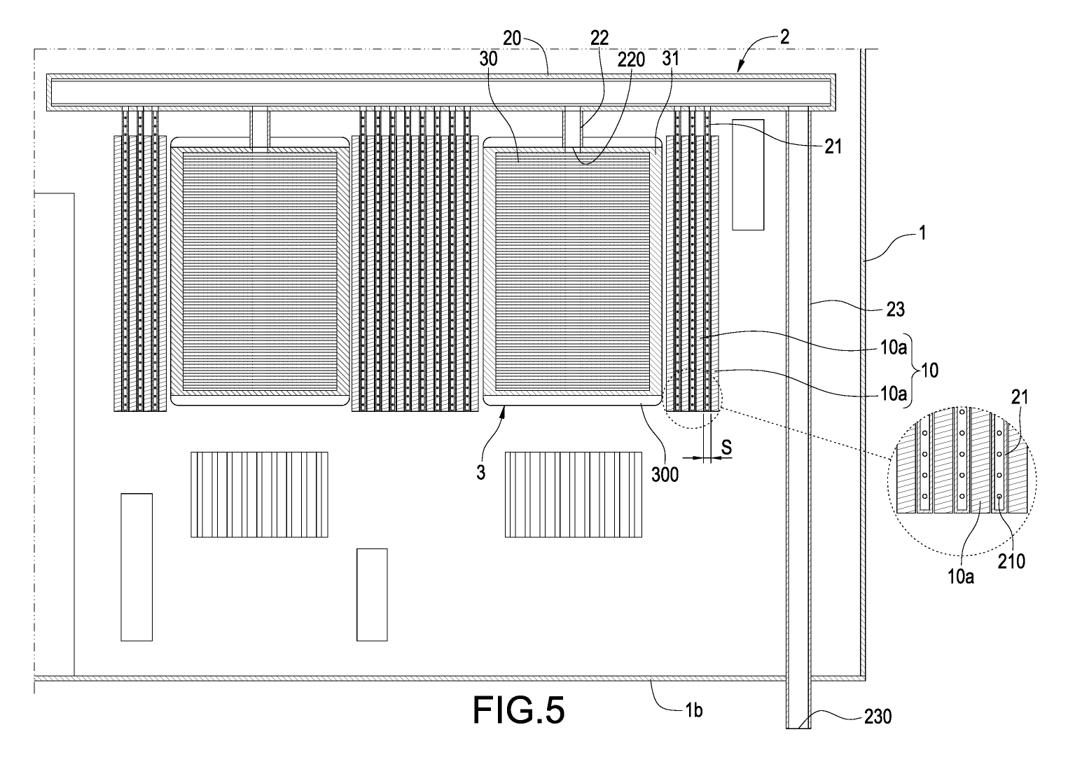

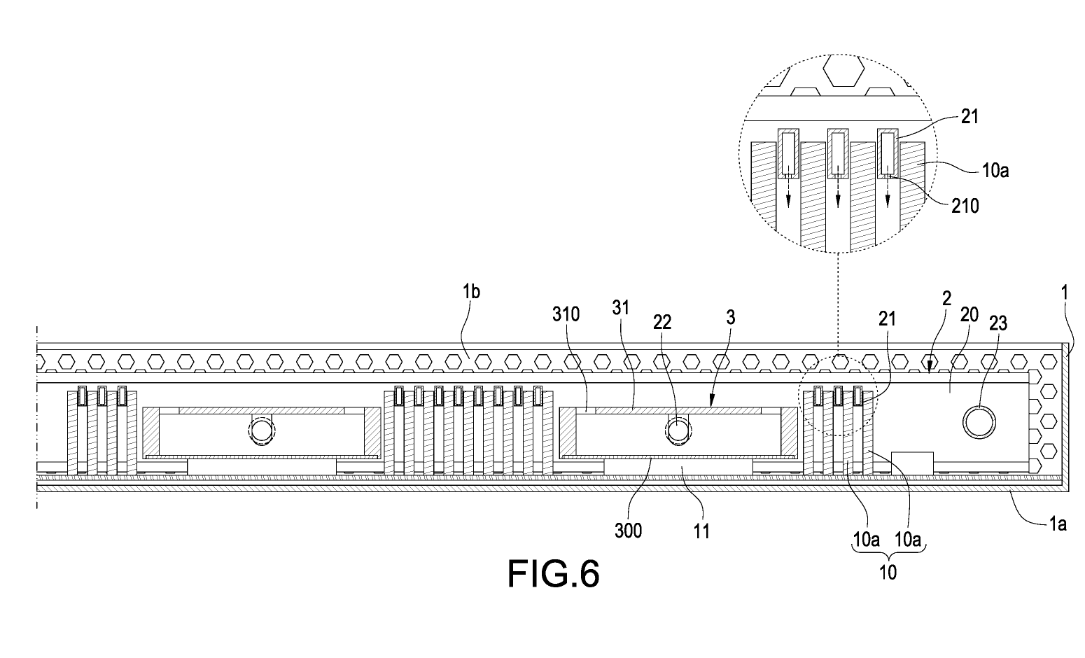

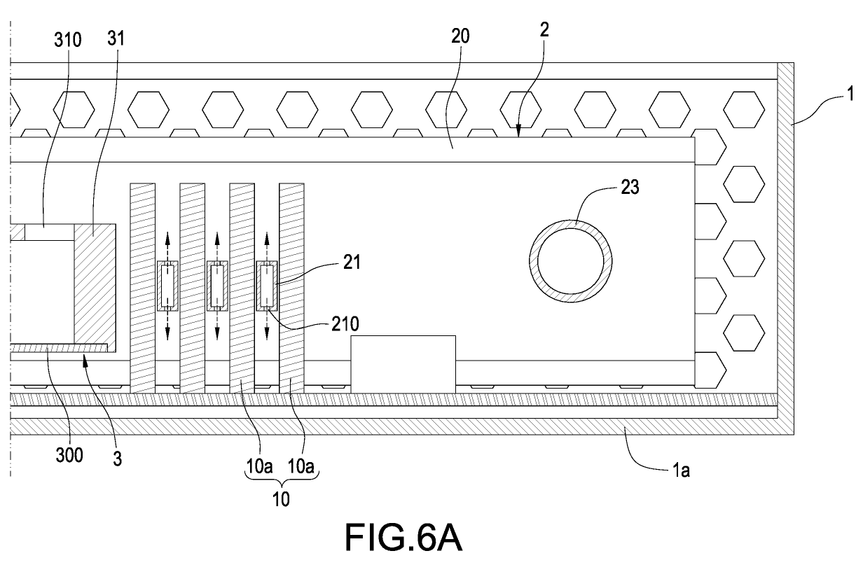

In other embodiments of the present disclosure as shown in FIGS. 4, 5, 6, the first jet-flow tube 21 is extended correspondingly to a length of each of the memories 10a, and the first jet 210 of the first jet-flow tube 21 is extended correspondingly to the length of each of the memories 10a to dissipate the heat in the arranged spacing S. As shown in FIG. 6, the first jet-flow tubes 21 is located on the upper area of the arranged spacing S such that the first jet 210 is located on a lower area of the first jet-flow tubes 21. On the other hand, when the first jet-flow tubes 21 is located on the lower area of the arranged spacing S, the first jet 210 is located on an upper area of the first jet-flow tubes 21. As shown in FIG. 6A, the first jet-flow tubes 21 is located on the middle area of the arranged spacing S, and two first jet 210 are respectively located on the upper area and the lower area of the first jet-flow tubes 21. In the embodiments above, the cross-sectional area of the first jet-flow tubes 21 must be smaller than a cross-sectional area of the arranged spacing S.

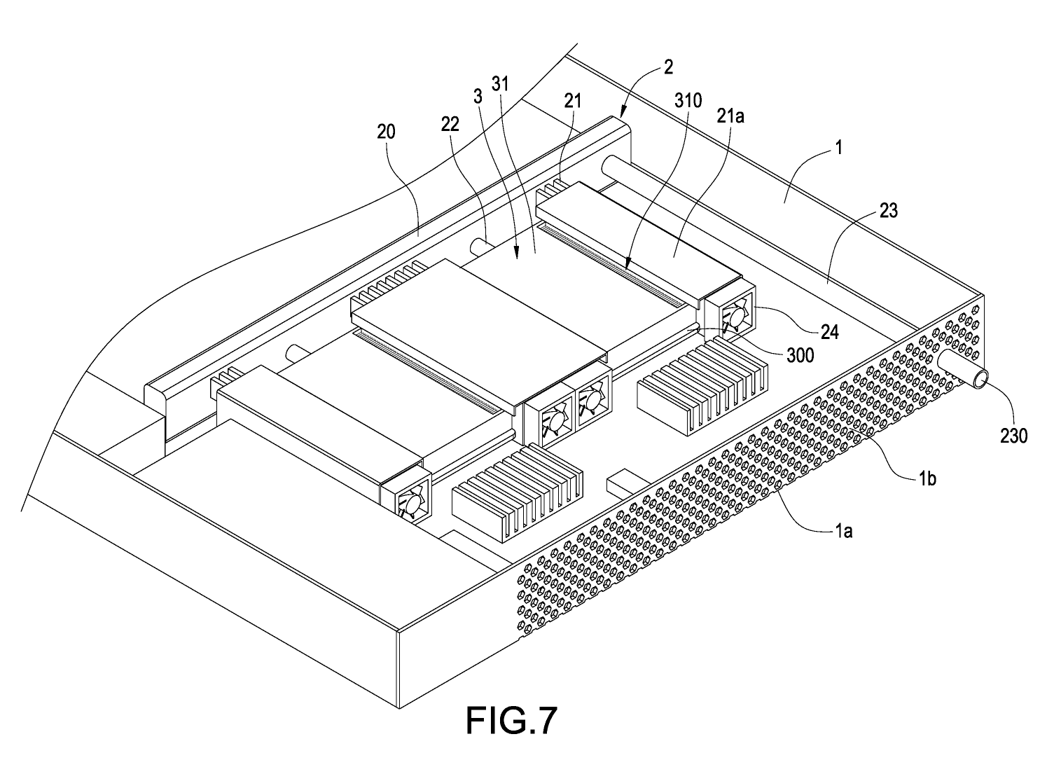

In addition, as shown in FIG. 7, the server jet-flow cooling device of the present disclosure further includes a fan 24 arranged on the memory module 10 away from the first jet-flow tube 21. The fan 24 may exhaust the memory module 10 when the shunter 20 provides the positive pressure, and the fan 24 may blow the memory module 10 when the shunter 20 provides the negative pressure, so as to assist the jet flow to dissipate heat more quickly.

It shall be understood that the present disclosure may have other types of embodiments, and a person with ordinary skills in the art of the technical field of the present disclosure may make various changes and modifications corresponding to the present disclosure without deviating the principle and substance of the present disclosure; however, such corresponding changes and modification shall be considered to be within the claimed scope of the present disclosure.

What is claimed is:

1. A server jet-flow cooling device, comprising:
a server, comprising a motherboard therein and at least one memory module, the memory module comprising a plurality of memories arranged at intervals on the motherboard, an arranged spacing being defined between any two adjacent memories; and
a shunt assembly, arranged in the server, the shunt assembly comprising a shunter and at least one first jet-flow tube communicated to the shunter;
wherein the first jet-flow tube is extended from a surface of the shunter, is extended into one of the arranged spacings, and comprises a first jet located in one of the arranged spacings to provide a positive pressure or a negative pressure.

2. The server jet-flow cooling device according to claim 1, wherein the shunt assembly further comprises a wind shield arranged on the memory module.

3. The server jet-flow cooling device according to claim 1, wherein the shunt assembly further comprises a fan arranged on the memory module away from the first jet-flow tube.

4. The server jet-flow cooling device according to claim 1, wherein the shunter is extended along an arranged direction of each of the memories to form elongated strip shape.

5. The server jet-flow cooling device according to claim 1, wherein the shunt assembly further comprises a connecting tube extended from the shunter and toward outside of the server to provide the positive pressure or the negative pressure.

6. The server jet-flow cooling device according to claim 1, wherein the first jet-flow tube is located on an upper area, a lower area, or a middle area of the arranged spacing.

7. The server jet-flow cooling device according to claim 1, wherein the first jet-flow tube is extended correspondingly to a length of each of the memories, each of the first jets is extended correspondingly to the length of each of the memories.

8. The server jet-flow cooling device according to claim 1, further comprising a cooling unit, wherein the sever further comprises at least one electronic member arranged on the motherboard, the cooling unit is arranged on the electronic member and comprises a cover covering the electronic member, the cover comprises a ventilation hole defined thereon, the shunt assembly further comprises at least one second jet-flow tube facing the electronic member.

9. The server jet-flow cooling device according to claim 8, wherein the cooling unit comprises a plurality of heat sinks attached on the electronic member, the cover covers each of the heat sinks.

10. The server jet-flow cooling device according to claim 9, further comprising a cold plate, wherein each of the heat sinks is attached on the electronic member through the cold plate.
